(19) United States
(12) Patent Application Publication
(10) Pub. No.: US 2018/0215093 A1
(43) Pub. Date: Aug. 2, 2018

(54) ADDITIVE MANUFACTURING WITH HIGH INTENSITY LIGHT

(71) Applicant: Carbon, Inc., Redwood City, CA (US)

(72) Inventor: Anant Chimmalgi, Los Altos, CA (US)

(21) Appl. No.: 15/883,392

(22) Filed: Jan. 30, 2018

Related U.S. Application Data
(60) Provisional application No. 62/451,908, filed on Jan. 30, 2017.

(51) Int. Cl. B29C 64/135; B33Y 10/00; B33Y 30/00; F21K 9/64; G03F 7/20

(52) U.S. Cl. CPC B29C 64/135; B33Y 10/00; G03F 7/70416; F21K 9/64; B33Y 30/00

(57) ABSTRACT

In a method of making a three dimensional object from a polymerizable liquid by stereolithography including irradiating the liquid with light projected from a light source through or across a patterning array and through an optically transparent build plate to the polymerizable liquid, as improvement includes employing as the light source (i) at least one or a plurality of laser diode array(s) or (ii) a light-sustained plasma.

### RELATED APPLICATION

This application claims priority to U.S. Provisional Application Ser. No. 62/451,908, filed Jan. 30, 3017, the disclosure of which is hereby incorporated by reference in its entirety.

### FIELD OF THE INVENTION

The present invention concerns methods and apparatus for carrying out stereolithography, particularly continuous liquid interface production, with high intensity light.

### BACKGROUND

“Stereolithography” refers to a set of additive manufacturing procedures in which a three dimensional object is produced from a polymerizable resin by sequential exposure to patterned light.

J. DeSimone et al., Continuous Liquid Interphase Printing, PCT Application No. WO2014/1268372 (published Aug. 21, 2014; see also U.S. Pat. No. 9,205,601) describes an improved stereolithography method from a window in which adhesion to the window is inhibited by allowing an inhibitor of polymerization, such as oxygen, to pass through the window, forming a non-polymerized release layer or “dead zone” that forms a “liquid interface” with the growing three-dimensional object, in turn enabling continuous or layerless production of the three-dimensional object from that interface (see also J. Tumbleston et al., Continuous liquid interface production of 3D Objects, Science 347, 1349-1352 (published online 16 Mar. 2015)).

The need for increased intensity light sources for carrying out continuous liquid interface production is noted in J. DeSimone et al., PCT Application WO 2015/195920 (published Dec. 23, 2015). For additional background, see EP 2186625 (Global Filtration Systems) US 2001/048184 (Ueno Takakuni), EP 0484086 (DuPont), and EP 2052693 (Envisiontec), all cited in the International Search Report of WO 2015/195920). In addition, it would be useful to have light sources that could readily generate multiple wavelengths, both for optimizing the process for different polymerizable liquids on different occasions, and for optimizing the process for the same polymerizable liquid during the production of different portions of the same object (including support portions) on individual occasions. None of the foregoing suggest the solutions to the problems of either increasing light intensity or providing selectively activatable multiple wavelengths as described herein.

### SUMMARY

According to some embodiments of the present invention, in a method of making a three dimensional object from a polymerizable liquid by stereolithography including irradiating the liquid with light projected from a light source through or across a patterning array and through an optically transparent build plate to the polymerizable liquid, as improvement includes employing as the light source (i) at least one or a plurality of laser diode array(s) or (ii) a light-sustained plasma.

In some embodiments, the light source is configured to generate light at at least two, three, four, five, or six different wavelengths (e.g., each wavelength differing from one another by at least 5 or 10 nanometers; e.g., the different wavelengths generated by inclusion of multiple different selectively activatable laser diodes, by inclusion of selectively activatable filters, etc., including combinations thereof). The light source is configured to generate light at a plurality of at least two, three, four or five wavelengths of the VUV, deep UV, UV, VIS, and NIR ranges. The light source concurrently generates light at a plurality of different wavelengths at which said polymerizable liquid is irradiated during the making of at least a portion of said three dimensional object. The light source sequentially generates light at a plurality of different wavelengths at which said liquid is irradiated during the making of at least a portion of said three-dimensional object.

In some embodiments, the method includes selectively controlling the composition of the plurality of different wavelengths at which said liquid is irradiated based on (a) the composition of said polymerizable liquid, (b) the resolution of at least a portion of said object, or (c) a combination thereof. The stereolithography may include continuous liquid interface production (CLIP).

In some embodiments, the polymerizable liquid is viscous at room temperature (e.g., 25 degrees Centigrade) (e.g., has a viscosity of at least 200, 300, 1,000, or 2,000 Centipoise, or more, at room temperature).

In some embodiments, an optically transparent member comprises a semipermeable member (e.g., a fluoropolymer), and the method comprises continuously maintaining a dead zone between said build plate and said optically transparent member (e.g., by feeding an inhibitor of polymerization through said optically transparent member, thereby creating a gradient of inhibitor in said dead zone and optionally in at least a portion of a gradient of polymerization zone). The polymerizable liquid comprises a free radical polymerizable liquid and the inhibitor comprises oxygen; or the polymerizable liquid comprises an acid-catalyzed or cationically polymerizable liquid, and the inhibitor comprises a base.

In some embodiments, the three-dimensional object is fabricated at a speed of at least 1 or 10 millimeters per hour, to 1,000 or 10,000 millimeters per hour, or more.

In some embodiments, the polymerizable liquid comprises a dual cure polymerizable liquid.

According to further embodiments according to the present invention, an apparatus for making a three dimensional object from a polymerizable liquid by stereolithography is provided. The apparatus includes a light source, a patterning array operatively associated with said light source, and an optically transparent build plate operatively associated with said patterning array. An improvement includes employing as the light source (i) at least one or a plurality of laser diode array(s) or (ii) a light-sustained plasma, as described above, each of which is incorporated herein by reference.

The disclosures of all United States patents and patent applications cited herein are to be incorporated by reference herein in their entirety.

### BRIEF DESCRIPTION OF THE DRAWINGS

FIG. 1 schematically illustrates methods and apparatus for carrying out continuous liquid interface production (CLIP), with the light source being shown generically.

The present invention is now described more fully hereinafter with reference to the accompanying drawings, in which embodiments of the invention are shown. This invention may, however, be embodied in many different forms and should not be construed as limited to the embodiments set forth herein; rather these embodiments are provided so that this disclosure will be thorough and complete and will fully convey the scope of the invention to those skilled in the art.

Like numbers refer to like elements throughout. In the figures, the thickness of certain lines, layers, components, elements or features may be exaggerated for clarity. Where used, broken lines illustrate optional features or operations unless specified otherwise.

The terminology used herein is for the purpose of describing particular embodiments only and is not intended to be limiting of the invention. As used herein, the singular forms “a,” “an” and “the” are intended to include plural forms as well, unless the context clearly indicates otherwise. It will be further understood that the terms “comprises” or “comprising,” when used in this specification, specify the presence of stated features, integers, steps, operations, elements components and/or groups or combinations thereof, but do not preclude the presence or addition of one or more other features, integers, steps, operations, elements, components and/or groups or combinations thereof.

As used herein, the term “and/or” includes any and all possible combinations or one or more of the associated listed items, as well as the lack of combinations when interpreted in the alternative (“or”).

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and claims and should not be interpreted in an idealized or overly formal sense unless expressly so defined herein. Well-known functions or constructions may not be described in detail for brevity and/or clarity.

It will be understood that when an element is referred to as being “on,” “attached” to, “connected” to, “coupled” with, “contacting,” etc., another element, it can be directly on, attached to, connected to, coupled with and/or contacting the other element or intervening elements can also be present. In contrast, when an element is referred to as being, for example, “directly on,” “directly attached” to, “directly connected” to, “directly coupled” with or “directly contacting” another element, there are no intervening elements present. It will also be appreciated by those of skill in the art that references to a structure or feature that is disposed “adjacent” another feature can have portions that overlap or underlie the adjacent feature.

Spatially relative terms, such as “under,” “below,” “lower,” “over,” “upper” and the like, may be used herein for ease of description to describe an element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus the exemplary term “under” can encompass both an orientation of over and under. The device may otherwise be oriented (rotated 90 degrees or at other orientations) and the spatially relative descriptors used herein interpreted accordingly. Similarly, the terms “upwardly,” “downwardly,” “vertical,” “horizontal” and the like are used herein for the purpose of explanation only, unless specifically indicated otherwise.

It will be understood that, although the terms first, second, etc., may be used herein to describe various elements, components, regions, layers and/or sections, these elements, components, regions, layers and/or sections should not be limited by these terms. Rather, these terms are only used to distinguish one element, component, region, layer and/or section, from another element, component, region, layer and/or section. Thus, a first element, component, region, layer or section discussed herein could be termed a second element, component, region, layer or section without departing from the teachings of the present invention. The sequence of operations (or steps) is not limited to the order presented in the claims or figures unless specifically indicated otherwise.

“VUV” as used herein refers to light in the vaccum ultraviolet wavelength range, typically 10 to 200 nanometers, and preferably 180 to 200 nanometers.

“DUV” or “Deep UV” as used herein refers to light in the deep ultraviolet wavelength range, particularly within the range of 201 or 205 nanometers to 350 nanometers.

“UV” as used herein refers to light in the ultraviolet wavelength range. While this may ordinarily be considered inclusive of the VUV and DUV range, it is herein intended to identify light in the 351 to 385 or 389 nanometer range, with “VUV” and “deep UV” referring to shorter wavelength ranges of UV light.

“VIS” as used herein refers to light in the visible (to human) wavelength range, particularly within the 390 nanometers to 700 nanometers range.

“NIR” or “near IR” as used herein refers to light in the near infra-red wavelength range, particularly from 705 or 710 nanometers to 1100 or 1400 nanometers.

1. General Methods and Apparatus.

As noted above, methods, apparatus, and polymerizable liquids or resins for “continuous liquid interface production” (or “CLIP”) are known and described in, for example, J. DeSimone et al., PCT Applications Nos. PCT/US2014/015486 (published as U.S. Pat. No. 9,211,678); PCT/US2014/015506 (published as U.S. Pat. No. 9,205,601), PCT/US2014/015497 (published as U.S. Pat. No. 9,216,546), J. Tumbleston, et al., Continuous liquid interface production of 3D Objects, Science 347, 1349-1352 (published online 16 Mar. 2015), and R. Janusziewcz et al., Layerless fabrication with continuous liquid interface production, Proc. Natl. Acad. Sci. USA 113, 11703-11708 (Oct. 18, 2016). Other approaches for carrying out continuous liquid interface production (or “CLIP”) include utilizing a liquid interface comprising an immiscible liquid (see L. Robeson et al., WO 2015/164234, published Oct. 29, 2015), generating oxygen as an inhibitor by electrolysis (see I. Craven et al., WO 2016/133759, published Aug. 25, 2016), and incorporating magnetically positionable particles to which the photoactivator is coupled into the polymerizable liquid (see J. Rolland, WO 2016/145182, published Sep. 15, 2016).

In addition, and as also noted above, methods and apparatus for implementing CLIP with step-wise or reciprocal advancement of the carrier, and growing three-dimensional object, away from the optically transparent member or “window” are known and described in, for example, A. Ermoshkin et al., Three-Dimensional Printing with Reciprocal Feeding of Polymerizable Liquid, PCT Application Publication No. WO 2015/195924.

Dual cure polymerizable liquids that can be used in carrying out the present invention are known and described in, for example, J. Rolland et al., PCT Applications PCT/US2015/036893 (see also US Patent Application Pub. No. US 2016/0136889), PCT/US2015/036902 (see also US Patent Application Pub. No. US 2016/0137838), PCT/US2015/036924 (see also US Patent Application Pub. No. US 2016/016077), and PCT/US2015/036946 (see also U.S. Pat. No. 9,453,142).

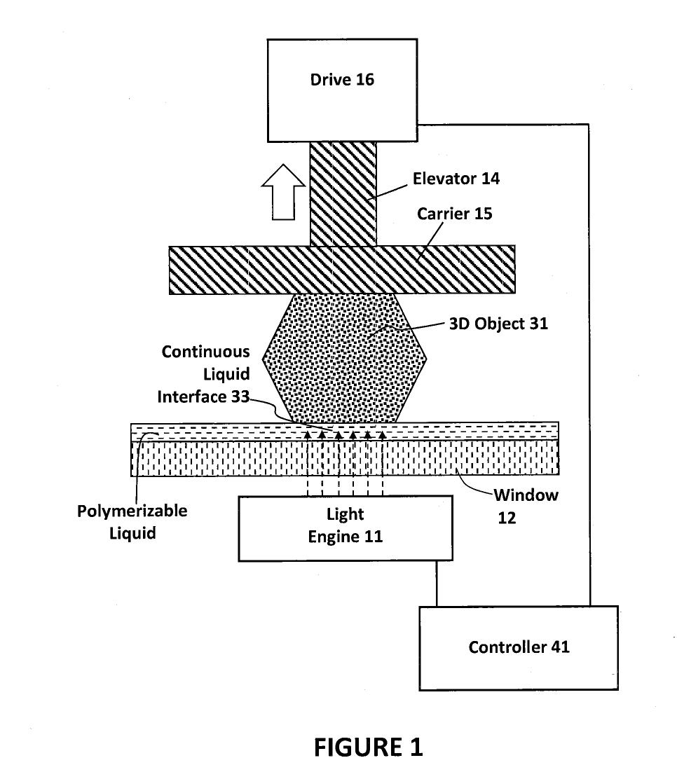

As noted above, FIG. 1 schematically illustrates an apparatus useful for carrying out the present invention. The larger upward arrow indicates the dominant direction of upward movement during continuous, stepped, and reciprocal (or “pumped”) modes of production. In general, the apparatus includes a light engine 11, a window (or “build plate”) 12, and elevator with drive assembly 14. A carrier platform (or “carrier plate”) 15 is typically mounted to the elevator and drive assembly as in conventional apparatus. Controller 41, drive 16, and the like may be implemented in accordance with known techniques. Other features known in the art (e.g., heaters, coolers, etc.) are not shown. Preferred light engines 11 are discussed below.

The window 12 may be impermeable or semipermeable to an inhibitor of polymerization (e.g. oxygen), depending on which particular approach for carrying out continuous liquid interface production is employed. In some embodiments, the window comprises a fluoropolymer, in accordance with known techniques.

A growing three-dimensional object 31 is shown being formed between the carrier platform (to which it is adhered) and the polymerizable resin 32, with a continuous liquid interface 33 between the polymerizable liquid 21 and the object 31.

While the schematic suggests that advancing away is accomplished by lifting the carrier on the elevator, note also that advancing away and partially retracting may be achieved by providing fixed or static carrier, and by mounting the window and light engine on an elevator beneath the same, which can then be lowered.

### Alternate Embodiments

While the light sources described herein are preferably implemented with CLIP, it will be appreciated that other techniques for stereolithography, including bottom-up and top-down additive manufacturing, may also be used. Such methods are known and described in, for example, U.S. Pat. No. 5,236,637 to Hull, U.S. Pat. Nos. 5,391,072 and 5,529,473 to Lawton, U.S. Pat. No. 7,438,846 to John, U.S. Pat. No. 7,892,474 to Shkolnik, U.S. Pat. No. 8,110,135 to El-Siblani, U.S. Patent Application Publication Nos. 2013/0292862 to Joyce, and US Patent Application Publication No. 2013/0295212 to Chen et al.

2. Implemention with Stacked Diode Laser Light Source.

Stacked diode lasers are known and described in, for example, A. Chimmalgi, Y. Vora, and R. Brunner, U.S. Pat. No. 9,110,037 (KLA-Tencor), D. Scifries, U.S. Pat. No. 4,716,568 (Spectra Diode); and P. Floyd, U.S. Pat. No. 5,920,766 (Xerox), the disclosures of which are incorporated herein by reference.

In some embodiments, an eighty to one-hundred-fold increase in output at the build plane compared to current LED light sources is feasible. While this is limited to the wavelengths of conventional LED and laser diodes, multiple diodes can be separately controlled to achieve a multi-wavelength light source for additive manufacturing.

In some embodiments, the light source includes a plurality of laser diode arrays.

In some embodiments, the plurality of laser diode arrays are configurable to provide an incident beam having different wavelength ranges. In some embodiments, at least some of the laser diode arrays form two dimensional (2D) stacks that have different wavelength ranges from each other. In some embodiments, a first set of one or more of the 2D stacks is formed from deep UV or UV based laser diodes. In some embodiments, a second set of one or more of the 2D stacks is formed from VIS based laser diodes. In some embodiments, a third set of one or more of the 2D stacks is formed from deep NIR based laser diodes.

In some embodiments, the 2D stacks are formed from diode bars that can be selectively activated to result in the incident beam having different wavelength ranges that together form a broadband range.

In some embodiments, a controller is configured to activate one or more laser diode arrays so that the incident beam has a specific wavelength range that is selected from the different wavelength ranges and configured to deactivate other one or more of the laser diode arrays so that the incident beam does not include any wavelengths that are not within the specific wavelength range.

In some embodiments, coupling optics are provided for receiving and combining output light from the activated one or more laser diode arrays. The coupling optics may include a spatial coupler or polarization coupler to combine output light having a same wavelength so as to achieve a higher net power than a power of individual diodes or diode bars of the laser diode arrays and a wavelength coupler for combining output light having different wavelength ranges.

In some embodiments, the wavelength ranges of the 2D stacks together cover a range between about 180 nm and about 1000 nm; and/or the wavelength ranges of the 2D stacks together include wavelengths in at least two, three, four or five of the VUV, deep UV, UV, VIS, and NIR ranges; and/or each 2D stack has a wavelength range width that is between about 15 to 80 nm; and/or each laser diode of each diode bar provides about 1 watt or more of power; and/or each 2D stack provides about 200 watts or more of power; and/or the diode bars of each 2D stack have a same wavelength range as its corresponding 2D stack; and/or the laser diode arrays include deep UV (ultra-violet) and UV continuous wave diode lasers; and/or the laser diode arrays include VIS (visible) and NIR (near infrared) continuous wave diode lasers.

3. Implementation with Light-Sustained Plasma Light Source.

Light-sustained plasma light sources are known and described in, for example, I. Bezel et al., U.S. Pat. No. 8,853,644 (KLA-Tencor), D. Smith, U.S. Pat. No. 7,435,982 (Energetiq), L. Wilson, A Chimmalgi et al., U.S. Pat. No. 9,263,238 (KLA-Tencor); and I. Bezel, A. Shchemelinin et al., et al., U.S. Pat. No. 9,390,902 (KLA-Tencor).

In some embodiments, the plasma source provides a broad band continuum light source (comprising of all wavelengths from <150 nm to well over 1000 nm). Hence, the light can be a broad band VUV and DUV, to UV, VIS, and NIR wavelengths. In some embodiments, achieving an eight to ten-fold increase in output at the build plane compared to current LED light sources is feasible (although this is wavelength specific). In addition, the broad band nature of the plasma source allows use of wavelengths that are not feasible with conventional LED light sources.

In some embodiments, the light source includes a light-sustained plasma. The light-sustained plasma light source may include: at least one laser configured to provide light; at least one reflector configured to focus the light from the at least one laser at a focal point of the reflector; and an enclosure substantially filled with a gas positioned at or near the focal point of the reflector. The light from the at least one laser light source at least partially sustains a plasma contained in the enclosure.

In some embodiments, the at least one light source includes at least two laser light sources whose light is combined by the at least one reflector.

In some embodiments, additional focusing optics are configured to collect and focus the light from the at least one laser light source at the focal point of the reflector.

In some embodiments, a filter assembly is configured to selectively (sequentially and/or concurrently) irradiate the polymerizable liquid with light at at least two, three, four or five of the VUV, deep UV, UV, VIS, and NIR ranges.

In some embodiments, the reflector comprises a shape that is modified to compensate for optical aberrations in the system.

In some embodiments, the gas is one or more of a noble gas, Xe, Ar, Ne, Kr, He, D₂, H₂, O₂, F₂, a metal halide, a halogen, Hg, Cd, Zn, Sn, Ga, Fe, Li, Na, an excimer forming gas, air, a vapor, a metal oxide, an aerosol, a flowing media, or a recycled media.

The foregoing is illustrative of the present invention, and is not to be construed as limiting thereof. The invention is defined by the following claims, with equivalents of the claims to be included therein.

That which is claimed is:

1. In a method of making a three dimensional object from a polymerizable liquid by stereolithography including irradiating the liquid with light projected from a light source through or across a patterning array and through an optically transparent build plate to the polymerizable liquid, the improvement comprising:
employing as the light source (1) at least one or a plurality of laser diode array(s) or (ii) a light-sustained plasma.

2. The method of claim 1, wherein said light source is configured to generate light at at least two, three, four, five, or six different wavelengths.

3. The method of claim 1, wherein each wavelength differs from one another by at least 5 or 10 nanometers, the different wavelengths generated by inclusion of multiple different selectively activatable laser diodes, by inclusion of selectively activatable filters, or combinations thereof.

4. The method of claim 1, wherein said light source is configured to generate light at a plurality of at least two, three, four or five wavelengths of the VUV, deep UV, UV, VIS, and NIR ranges.

5. The method of claim 1, wherein said light source concurrently generates light at a plurality of different wavelengths at which said polymerizable liquid is irradiated during the making of at least a portion of said three dimensional object.

6. The method of claim 1, wherein said light source sequentially generates light at a plurality of different wavelengths at which said liquid is irradiated during the making of at least a portion of said three-dimensional object.

7. The method of claim 2, further comprising selectively controlling the composition of said plurality of different wavelengths at which said liquid is irradiated based on (a) the composition of said polymerizable liquid, (b) the resolution of at least a portion of said object, or (c) a combination thereof.

8. The method of claim 1, wherein said stereolithography comprises continuous liquid interface production (CLIP).

9. The method of claim 1, wherein said polymerizable liquid is viscous at room temperature.

10. The method of claim 1, wherein: said optically transparent member comprises a semipermeable member, and said method comprises continuously maintaining a dead zone between said build plate and said optically transparent member.

11. The method of claim 10, wherein: said polymerizable liquid comprises a free radical polymerizable liquid and said inhibitor comprises oxygen; or said polymerizable liquid comprises an acid-catalyzed or cationically polymerizable liquid, and said inhibitor comprises a base.

12. The method of claim 1, wherein said three-dimensional object is fabricated at a speed of at least 1 or 10 millimeters per hour, to 1,000 or 10,000 millimeters per hour, or more.

13. The method of claim 1, wherein said polymerizable liquid comprises a dual cure polymerizable liquid.

14. The method of claim 1, wherein said light source comprises a plurality of laser diode arrays.

15. The method of claim 14, optionally wherein said plurality of laser diode arrays are configurable to provide an incident beam having different wavelength ranges, optionally wherein at least some of the laser diode arrays form two dimensional (2D) stacks that have different wavelength ranges from each other, optionally wherein a first set of one or more of the 2D stacks is formed from deep UV or UV based laser diodes, optionally a second set of one or more of the 2D stacks is formed from VIS based laser diodes, and optionally a third set of one or more of the 2D stacks is formed from deep NIR based laser diodes.

16. The method of claim 15, wherein the 2D stacks are formed from diode bars that can be selectively activated to result in the incident beam having different wavelength ranges that together form a broadband range.

17. The method of claim 14, further comprising a controller configured to activate one or more laser diode arrays so that the incident beam has a specific wavelength range that is selected from the different wavelength ranges and configured to deactivate other one or more of the laser diode arrays so that the incident beam does not include any wavelengths that are not within the specific wavelength range.

18. The method of claim 14, further comprising coupling optics for receiving and combining output light from the activated one or more laser diode arrays.

19. The method of claim 18, wherein the coupling optics comprises a spatial coupler or polarization coupler to combine output light having a same wavelength so as to achieve a higher net power than a power of individual diodes or diode bars of the laser diode arrays and a wavelength coupler for combining output light having different wavelength ranges.

20. The method of claim claim 14, wherein:
the wavelength ranges of the 2D stacks together cover a range between about 180 nm and about 1000 nm; and/or
the wavelength ranges of the 2D stacks together include wavelengths in at least two, three, four or five of the VUV, deep UV, UV, VIS, and NIR ranges; and/or
wherein each 2D stack has a wavelength range width that is between about 15 to 80 nm; and/or
each laser diode of each diode bar provides about 1 watt or more of power; and/or
each 2D stack provides about 200 watts or more of power; and/or
the diode bars of each 2D stack have a same wavelength range as its corresponding 2D stack; and/or
the laser diode arrays include deep UV (ultra-violet) and UV continuous wave diode lasers; and/or
the laser diode arrays include VIS (visible) and NIR (near infrared) continuous wave diode lasers.

21. The method of claim 1, wherein said light source comprises a light-sustained plasma.

22. The method of claim 21, wherein said light-sustained plasma light source comprises: at least one laser configured to provide light; at least one reflector configured to focus the light from the at least one laser at a focal point of the reflector; and an enclosure substantially filled with a gas positioned at or near the focal point of the reflector, wherein the light from the at least one laser light source at least partially sustains a plasma contained in the enclosure.

23. The method of claim 22, wherein the at least one light source comprises at least two laser light sources whose light is combined by the at least one reflector.

24. The method of claim 21, further comprising additional focusing optics configured to collect and focus the light from the at least one laser light source at the focal point of the reflector.

25. The method of claim 21, further comprising a filter assembly configured to selectively (sequentially and/or concurrently) irradiate said polymerizable liquid with light at at least two, three, four or five of the VUV, deep UV, UV, VIS, and NIR ranges.

26. The method of claim 22, wherein the reflector comprises a shape that is modified to compensate for optical aberrations in the system.

27. The method of claim 22, wherein the gas is one or more of a noble gas, Xe, Ar, Ne, Kr, He, D₂, H₂, O₂, F₂, a metal halide, a halogen, Hg, Cd, Zn, Sn, Ga, Fe, Li, Na, an excimer forming gas, air, a vapor, a metal oxide, an aerosol, a flowing media, or a recycled media.

28. In an apparatus for making a three dimensional object from a polymerizable liquid by stereolithography, the apparatus including a light source, a patterning array operatively associated with said light source, and an optically transparent build plate operatively associated with said patterning array, the improvement comprising:
employing as the light source (i) at least one or a plurality of laser diode array(s) or (ii) a light-sustained plasma, as described in any of claims 1 to 26 above, each of which is incorporated herein by reference.
